(19) United States
(12) Patent Application Publication
(10) Pub. No.: US 2019/0206894 A1
(43) Pub. Date: Jul. 4, 2019

(54) DISPLAY SYSTEMS WITH NON-DISPLAY AREAS

(71) Applicant: a.u. Vista Inc., Milpitas, CA (US)

(72) Inventors: Seok-Lyul Lee, Hsinchu (TW); Fang-Chen Luo, Milpitas, CA (US)

(21) Appl. No.: 15/856,411

(22) Filed: Dec. 28, 2017

(51) Int. Cl. H01L 27/12; G02F 1/1368; G02F 1/1362; G02F 1/1345

(52) U.S. Cl. CPC H01L 27/124; G02F 1/1368; G02F 2001/133388; G02F 1/13454; G02F 1/136286

(57) ABSTRACT

A representative display system includes: a first substrate defined by an outer periphery and having an edge region; a display area, inward of the edge region, defined by a plurality of sub-pixels; a non-display area positioned inward of the edge region; data lines; and, dummy data lines. The data lines include a first set extending along a first direction from the edge region at a first side to the edge region at a second side of the first substrate; a second set extending along the first direction from the edge region at the first side to a first side of the non-display area; and a third set extending along the first direction from a second side of the non-display area to the edge region at the second side of the first substrate. The dummy data lines extend in the first direction and are interleaved with the data lines, with at least some of the dummy data lines configured to route signals from the second set to corresponding data lines of the third set.

### BACKGROUND

### Technical Field

The disclosure generally relates to displays.

### Description of the Related Art

Various display technologies (e.g., liquid crystal displays (LCDs)) are widely used in displays for electronic devices, such as laptops, smart phones, digital cameras, billboard-type displays, and high-definition televisions. In addition, other display technologies, such as organic light-emitting diodes (OLEDs) and electronic paper displays (EPDs), are gaining in public attention.

LCD panels may be configured as disclosed, for example, in Wu et al., U.S. Pat. No. 6,956,631, which is assigned to AU Optronics Corp., the parent company of the assignee of the current application, and hereby incorporated by reference in its entirety. As disclosed in Wu et al. FIG. 1, the LCD panel may comprise a top polarizer, a lower polarizer, a liquid crystal cell, and a back light. Light from the back light passes through the lower polarizer, through the liquid crystal cell, and then through the top polarizer. As further disclosed in Wu et al. FIG. 1, the liquid crystal cell may comprise a lower glass substrate and an upper substrate containing color filters. A plurality of pixels comprising thin film transistor (TFT) devices may be formed in an array on the glass substrate, and a liquid crystal compound may be filled into the space between the glass substrate and the color filter forming a layer of liquid crystal material.

Still, the structure of TFTs in displays may be various. For instance, The TFTs, gate and data lines, and pixel electrodes may be formed in a multilayer structure such as that shown in FIGS. 1 and 2E of Lai et al., U.S. Pat. No. 7,170,092 and in its division U.S. Pat. No. 7,507,612, both of which are assigned to AU Optronics Corp., the parent company of the assignee of the current application, and both of which are hereby incorporated by reference in their entireties. The multilayer structure may comprise a first conducting layer, a first insulating layer, a semiconductor layer, a doped semiconductor layer, and a second conducting layer disposed in sequence on the substrate. It may further comprise a second insulating layer and a pixel electrode disposed on the second insulating layer. The first conducting layer may comprise at least one of a gate line or a gate electrode. The doped semiconductor layer may comprise a source and a drain. The second conducting layer may comprise a source electrode and a drain electrode. The multilayer structure may be formed using a series of wet and dry etching processes, for example as disclosed in Lai et al. FIGS. 2A-2D.

Additional techniques for forming TFTs are disclosed in Chen, U.S. Pat. No. 7,652,285, which is assigned to AU Optronics Corp., the parent company of the assignee of the current application, and hereby incorporated by reference in its entirety. As disclosed in Chen, to form the channel of the TFT, the second metal layer is etched in order to open a portion of the second metal layer over the gate electrode and to separate the source region and drain region. This etching can be performed in multiple ways, including the back-channel etching process disclosed for example in Chen FIGS. 2A-2E and the etch stop process disclosed for example in Chen FIGS. 5A-5D and 6. Chen discloses that TFT leakage currents may be reduced by adding a spacer layer formed at the sidewalls of the conductive doped amorphous silicon layer, isolating the conductive amorphous silicon layer from the insulating layer. Chen discloses that this spacer layer can be formed by oxidizing the exposed surface of the conductive amorphous silicon layer after the etch of the second metal layer is performed. Chen discloses that this surface may be oxidized by a number of different techniques, including oxygen plasma ashing, or the use of ozone plasma in the presence of carbon tetrafluoride and sulfur hexafluoride gases

As explained in Sawasaki et al., U.S. Pat. No. 7,557,895, which is assigned to AU Optronics Corp., the parent company of the assignee of the current application, and hereby incorporated by reference in its entirety, the thickness of the liquid crystal layer typically must be uniformly controlled, in order to avoid unevenness in brightness across the LCD panel. As disclosed in Sawasaki et al., the required uniformity may be achieved by disposing a plurality of pillar spacers between the TFT substrate and the color filter substrate. As further disclosed in Sawasaki et al., the pillar spacers may be formed with different heights, such that some spacers have a height that is greater than the gap between the substrates and other spacers have a height that is less than the gap between the substrates. This configuration may permit the spacing between the substrates to vary with temperature changes but also prevent excessive deformation when forces are applied to the panel.

Sawasaki et al. further discloses a method for assembling the substrates with the liquid crystal material between them. This method comprises steps of preparing the two substrates, coating a sealing material on the circumference of the outer periphery of one of the pair of substrates, dropping an appropriate volume of liquid crystal on one of the pair of substrates, and filling in the liquid crystal between the pair of substrates by attaching the pair of substrates in a vacuum followed by returning the attached pair of substrates to atmospheric pressure .

In LCD panels, the semiconductor material making up the TFT channel may be amorphous silicon. However, as disclosed in Chen, U.S. Pat. No. 6,818,967, which is assigned to AU Optronics Corp., the parent company of the assignee of the current application, and hereby incorporated by reference in its entirety, poly-silicon channel TFTs offer advantages over amorphous silicon TFTs, including lower power and greater electron migration rates. Poly-silicon may be formed by converting amorphous silicon to poly-silicon via a laser crystallization or laser annealing technique. Use of the laser permits fabrication to occur at temperatures below 600° C., and the fabricating technique is thus called low temperature poly-silicon (LTPS). As disclosed in Chen, the re-crystallization process of LTPS results in the formation of mounds on the surface of the poly-silicon layer, and these mounds impact the current characteristics of the LTPS TFT. Chen discloses a method to reduce the size of the LTPS surface mounds, by performing a first anneal treatment, then performing a surface etching treatment, for example using a solution of hydrofluoric acid, and then performing a second anneal treatment. The resulting LTPS surface has mounds with a height/width ratio of less than 0.2. A gate isolation layer, gate, dielectric layer, and source and drain metal layers can then be deposited above the LTPS layer to form a complete LTPS TFT.

As disclosed in Sun et al., U.S. Pat. No. 8,115,209, which is assigned to AU Optronics Corp., the parent company of the assignee of the current application, and hereby incorporated by reference in its entirety, a disadvantage of LTPS TFTs compared to amorphous silicon TFTs is a relatively large leakage current during TFT turn off. Use of multiple gates reduces leakage current, and Sun et al. discloses a number of different multi-gate structures for a polycrystalline silicon TFT, including those shown in Sun et al. FIGS. 2A-2B and 3-6.

An alternative to LCD devices is the active matrix organic light-emitting device (OLED), as disclosed for example in Huang, U.S. Pat. No. 6,831,410, which is assigned to AU Optronics Corp., the parent company of the assignee of the current application, and hereby incorporated by reference in its entirety. As disclosed in Huang, a TFT is formed over a substrate. An insulating layer is formed, covering the TFT. A contact opening is formed in the insulating layer, exposing the drain terminal of the TFT, and an anode layer is formed over the insulating layer and the exposed opening, forming a contact between the anode layer and the TFT drain terminal. A light-emitting layer is formed over the anode layer, and a cathode layer is formed over the light-emitting layer. As explained in Huang, there is a risk that the cathode layer will form a short circuit with the anode layer via the contact opening. To prevent such short circuits, Huang discloses depositing a planarization layer that fills the space above the contact. The light-emitting and cathode layers are then formed over the planarization layer.

Conventionally, regardless of the display technology used, displays tend to be rectangular in shape and provide continuous display areas across the lengths and widths of the display surfaces of the displays. In some applications, however, display configurations other than those exhibiting continuous display areas are desirable - a desire that existing technology has been inadequate for addressing.

### SUMMARY

Display systems with non-display areas are provided. In one embodiment, a display system comprises: a first substrate defined by an outer periphery and having an edge region extending inwardly from the outer periphery; a display area defined by a plurality of sub-pixels arranged in an array, the display area being positioned inward of the edge region; a non-display area positioned inward of the edge region; a plurality of data lines and a plurality of dummy data lines. The plurality of data lines comprise: a first set of the data lines extending along a first direction from the edge region at a first side of the first substrate to the edge region at a second side of the first substrate; a second set of the data lines extending along the first direction from the edge region at the first side of the first substrate to a first side of the non-display area; and a third set of the data lines extending along the first direction from a second side of the non-display area to the edge region at the second side of the first substrate. The plurality of dummy data lines extend in the first direction and interleaved with the plurality of data lines, with at least some of the plurality of dummy data lines being configured to route data signals from data lines of the second set of the data lines to corresponding data lines of the third set of the data lines.

In some embodiments, a display system further comprises: gate control on array (GOA) circuitry in the edge region and extending in the first direction; and a plurality of scan lines electrically connected to the GOA circuitry and extending along a second direction.

In some embodiments, a display system of claim 1, the plurality of dummy data lines comprise a first set of dummy data lines interleaved with the first set of the data lines, a second set of dummy data lines interleaved with the second set of the data lines, and a third set of dummy data lines interleaved with the third set of the data lines.

In some embodiments, a display system further comprises: a plurality of start data bus lines comprising a first set of start data bus lines connecting the data lines of the first set of the data lines to corresponding dummy data lines of the first set of dummy data lines, and a second set of start data bus lines connecting the data lines of the second set of the data lines to corresponding dummy data lines of the second set of dummy data lines; and a plurality of end data bus lines connecting the dummy data lines of the second set of dummy data lines to corresponding data lines of the third set of the data lines.

In some embodiments, the second set of the data lines comprises a first data line and a second data line; the second set of dummy data lines comprises a first dummy data line and a second dummy data line; and the second data line and the second dummy data line are positioned between the first data line and the first dummy data line.

In some embodiments, the non-display area exhibits a centerline extending along the first direction; and the first data line is positioned closer to the centerline than is the second data line.

In some embodiments, the plurality of start data bus lines and the plurality of end data bus lines extend along the second direction.

In some embodiments, the non-display area is surrounded by the display area.

In some embodiments, the display system further comprises a fourth set of the data lines extending along the first direction from the edge region at the first side of the first substrate to the edge region at the second side of the first substrate; and the second set of the data lines and the third set of the data lines are positioned between the first set of the data lines and the fourth set of the data lines.

In some embodiments, a display system further comprises: first GOA circuitry in the edge region and extending in the first direction; second GOA circuitry in the edge region and extending in the first direction; a first plurality of scan lines electrically connected to the first GOA circuitry and extending along a second direction from the edge region to a third side of the non-display area; and a second plurality of scan lines electrically connected to the second GOA circuitry and extending along the second direction from the edge region to a fourth side of the non-display area.

In some embodiments, a display system further comprises data control circuitry positioned only in the edge region at the first side of the first substrate, the data driving circuitry being configured to provide the data signals directly to the first set of the data lines and the second set of the data lines.

In some embodiments, the data control circuitry is further configured to provide the data signals to the third set of the data lines via the second set of the data lines and the at least some of the plurality of dummy data lines.

In some embodiments, each of the plurality of dummy data lines extends between sub-pixels of a corresponding pair of the plurality of sub-pixels.

In some embodiments, each of the plurality of data lines is configured to provide a corresponding data signal to both sub-pixels of the corresponding pair of sub-pixels.

In some embodiments, a first of the dummy data lines extends between a first pair of sub-pixels, the first pair of sub-pixels including a first sub-pixel and a second sub-pixel; the display system further comprises a first scan line and a second scan line, each of which extends along a second direction; and the first scan line is electrically connected to the first sub-pixel and the second scan line is electrically connected to the second sub-pixel.

In some embodiments, a display system further comprises a second pair of sub-pixels adjacent in the array to the first pair of sub-pixels, the second pair of sub-pixels including a third sub-pixel and a fourth sub-pixel; the first of the dummy data lines extends between the second pair of sub-pixels; and the second scan line is electrically connected to the fourth sub-pixel.

In some embodiments, the first substrate comprises a third side extending from the first side to the second side, and a fourth side extending from the first side to the second side; each of the third side and the fourth side is longer than the first side and the second side; and the third side and the fourth side are aligned with the first direction.

In some embodiments, a display system further comprises a first pair of sub-pixels and second pair of sub-pixels positioned in a first column of the array, the first pair of sub-pixels including a first sub-pixel and a second sub-pixel, the second pair of sub-pixels including a third sub-pixel and a fourth sub-pixel, the second sub-pixel being positioned adjacent to the third sub-pixel; a first data line of the plurality of data lines is electrically connected to each of the first sub-pixel and the second sub-pixel and extends therebetween; a second data line of the plurality of data lines is electrically connected to each of the third sub-pixel and the fourth sub-pixel and extends therebetween; and a first of the dummy data lines extends between the first pair of sub-pixels and the second pair of sub-pixels.

In some embodiments, a display system further comprises a first scan line and a second scan line, each of which extends along a second direction; and the first scan line is electrically connected to the first sub-pixel and the third sub-pixel, and the second scan line is electrically connected to the second sub-pixel and the fourth sub-pixel.

In some embodiments, a first of the plurality of dummy data lines is electrically coupled to a common signal (Vcom).

Other objects, features, and/or advantages will become apparent from the following detailed description of the preferred but non-limiting embodiments. The following description is made with reference to the accompanying drawings.

### BRIEF DESCRIPTION OF THE DRAWINGS

FIG. 1 is a schematic diagram of a portion of an embodiment of a display system.

FIG. 2 is a schematic diagram of a portion of another embodiment of a display system.

FIG. 3 is a schematic diagram of another embodiment of a display system.

FIG. 4 is a schematic diagram of a portion of an embodiment of array showing several adjacent sub-pixels.

FIG. 5 is a timing diagram showing charting cycles of several sub-pixels from FIG. 4.

FIG. 6 is a schematic diagram of a portion of an embodiment of array showing a pair of sub-pixels.

FIGS. 7-12 are schematic diagrams of layouts that may be used in forming an embodiment of a pair of sub-pixels.

FIG. 13 is a flowchart illustrating an embodiment of a method for controlling an array that uses pairs of sub-pixels.

FIG. 14 is a schematic diagram of a portion of an embodiment of an array showing several adjacent sub-pixels.

FIG. 15 is a schematic diagram of a portion of another embodiment of an array showing several adjacent sub-pixels.

### DETAILED DESCRIPTION

For ease in explanation, the following discussion describes embodiments in the context of a display system that uses LCD technology. It is to be understood that the invention is not limited in its application to the details of the particular arrangements shown since the invention is capable of other embodiments, such as those using OLED or EPD technologies, for example. Also, the terminology used herein is for the purpose of description and not of limitation.

In this regard, display systems with non-display areas are provided. As will be described in greater detail below, such systems may involve the use data lines that are interleaved with dummy data lines for routing data signals around the non-display areas. Preferred embodiments of the present invention will now be described with reference to the drawings.

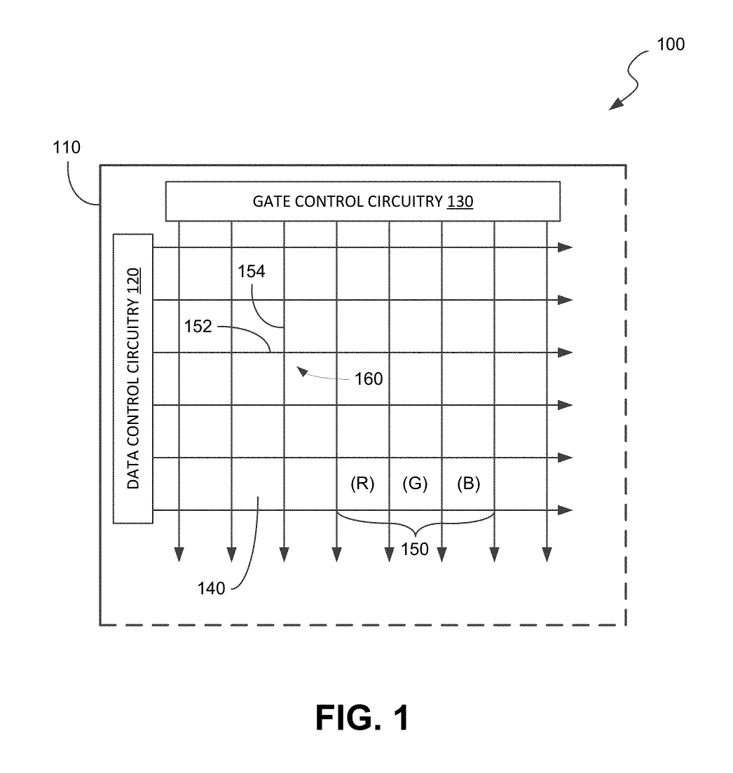

With reference to FIG. 1, a portion of an embodiment of a display system 100 is depicted. Fundamentally, display system 100 includes an LCD panel 110 with data control circuitry 120 and gate control circuitry 130 (e.g., gate control on array (GOA) circuitry). The circuits and functions in the embodiments of the present invention can be implements by hardware, software or a combination of hardware and software such as microcontrollers, application-specific integrated circuits (ASIC) and programmable microcontrollers.

In keeping with the description of FIG. 1, panel 110 incorporates a plurality of pixels (typically thousands of pixels, e.g., pixels 140, 150), which are arranged in a two-dimensional array comprising a plurality of rows and columns. For ease in illustration, only a few pixels are illustrated in FIG. 1. As is known, in a thin film transistor (TFT) LCD panel, a pixel is typically formed from three pixel elements (sub-pixels): one red, one green, and one blue, although various configurations may be used. For instance, pixel 150 is depicted as including three sub-pixels—a red sub-pixel (R), a green sub-pixel (G), and a blue sub-pixel (B). One or more transistors and one or more storage capacitors are typically coupled to each sub-pixel, thereby forming driving circuitry for the associated sub-pixel.

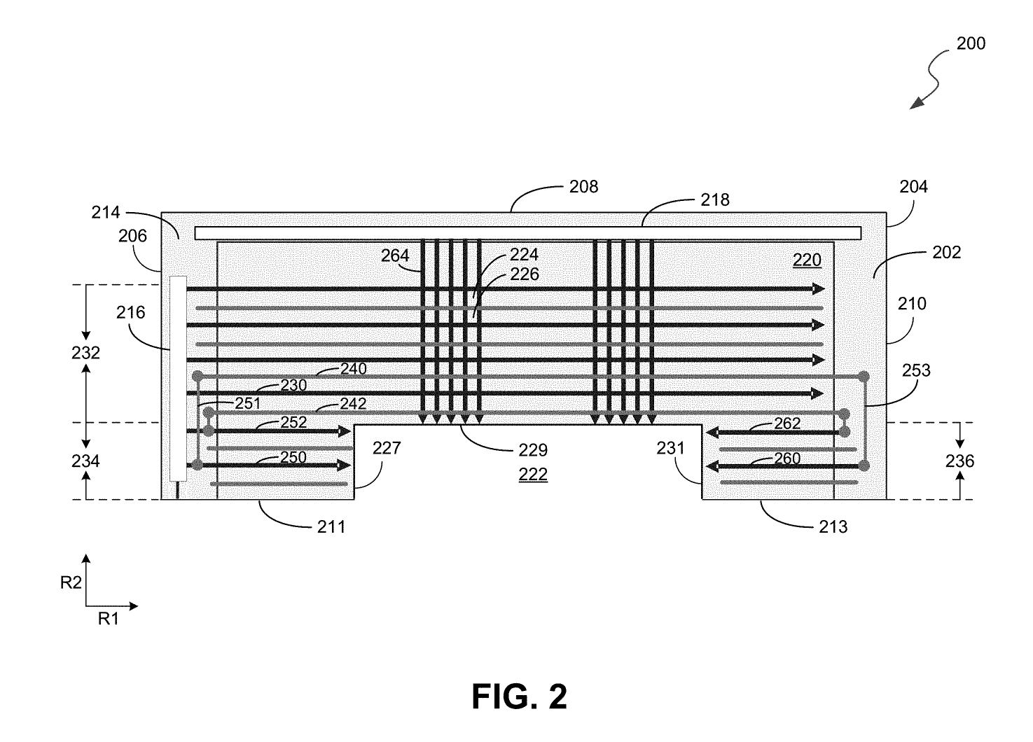

The transistors of all pixels in a given row typically have their gate electrodes connected to a gate (scan) line (e.g., line 152), and their source electrodes connected to a data line (e.g., line 154). The gate control circuitry 130 and data control circuitry 120 control the voltage applied to the respective gate and data lines to individually address each sub-pixel in the panel. By controllably pulsing the respective sub-pixel driving transistors, the control circuitry can control the transmissivity of each sub-pixel, and thereby control the color of each pixel. The storage capacitors assist in maintaining the charge across each pixel between successive pulses (which are delivered in successive frames). It should be noted that the portion of display system 100 depicted in FIG. 1 exhibits a continuous display area. FIG. 2, however, depicts a portion of another embodiment of a display system showing detail of an incorporated non-display area.

As shown in FIG. 2, display system 200 includes a substrate 202 defined by an outer periphery 204 that extends along sides 206, 208, 210, 211, 213, 227, 229, and 231. An edge region 214 extends inwardly from outer periphery 204 along sides 206, 208, 210, 213, 231, 229, 227, and 211. Substrate 202 is generally rectangular in shape with the exception of the portion defined by sides 227, 229, and 231, which form a cut-out for providing a non-display area. In this regard, display system 200 incorporates a display area 220 and a non-display area 222. Display area 220, positioned inward of edge region 214, is defined by a plurality of sub-pixels (e.g., 224 and 226) that are configured to display data, with only several of the multitude of sub-pixels shown arranged in an array. Non-display area 222 also is positioned inward of edge region 214 (but lacks sub-pixels) and is defined, at least in part, by sides 227, 229, and 231. In particular, the non-display area does not include sub-pixels or any associated signal lines (e.g., gate lines and data lines). In this embodiment, non-display area 222 is an empty area (e.g., substrate 202 is not located in non-display area 222).

Additionally, display system 200 incorporates data control circuitry 216 and gate control circuitry 218, each of which is positioned in edge region 214. In this embodiment, data control circuitry 216 is positioned along a short side 206 of the panel, and gate control circuitry 218 is positioned along a long side 208. A plurality of data lines (e.g., data line 230) and a plurality of dummy data lines (e.g., dummy data line 240) extend from their respectively control circuitry throughout display area 220. In particular, the data lines include: a first set 232 of data lines that extend along a first direction R1 from the edge region at side 206 to the edge region at side 210; a second set 234 of data lines that extend along the first direction R1 from the edge region at side 206 to side 227 of the non-display area; and, a third set 236 of data lines that extend along the first direction R1 from side 231 of the non-display area to the edge region at side 210. The dummy data lines also extend in the first direction R1 and are interleaved with the plurality of data lines. In some embodiments, the data lines and dummy data lines are provided in an alternating configuration.

Due to non-display area 222 extending across the paths of some of the data lines, at least some of the dummy data lines are configured to route data signals around the non-display area. As such, at least some of the dummy data lines (e.g., dummy data lines 240, 242) are configured to route data signals from data lines of the second set 234 of the data lines to corresponding data lines of the third set 236 of the data lines. For example, in this embodiment, dummy data line 240 routes data signals provided to data line 250 of the second set 234 of data lines by data control circuitry 216 to data line 260 of the third set 236 of data lines, and dummy data line 242 routes data signals provided to data line 252 of the second set 234 of data lines to data line 262 of the third set 236 of data lines. Of note, the dummy data lines are not directly coupled to the data control circuitry as are the data lines. So configured, data signals are routed from the data control circuitry to the back side of the non-display area by some of the dummy data lines.

In order to route the data signals to the back side of non-display area 222 (i.e., the side opposite the data control circuitry), a plurality of start data bus lines (e.g., start data bus line 251) and a plurality of end data bus lines (e.g., end data bus line 253) are provided. In particular, the start data bus lines electrically connect the data lines of set 234 of data lines to corresponding dummy data lines. For example, start data bus line 251 electrically connects data line 250 to dummy data line 240. Additionally, the end data bus lines electrically connect the dummy data lines to corresponding data lines of set 236 of the data lines. For example, end data bus line 253 electrically connects dummy data line 240 to data line 260. In some embodiments, the start data bus lines and the end data bus lines extend along the second direction R2 and are located in the edge region.

In some embodiments, gate control circuitry 218 is configured as gate driver on array (GOA) circuitry. Gate control circuitry 218 extends in the first direction R1 and is electrically connected to a plurality of scan lines (e.g., scan line 264) that extend along a second direction R2. The first direction R1 and the second direction R2 are interlaced and, in some embodiments, are perpendicular to each other.

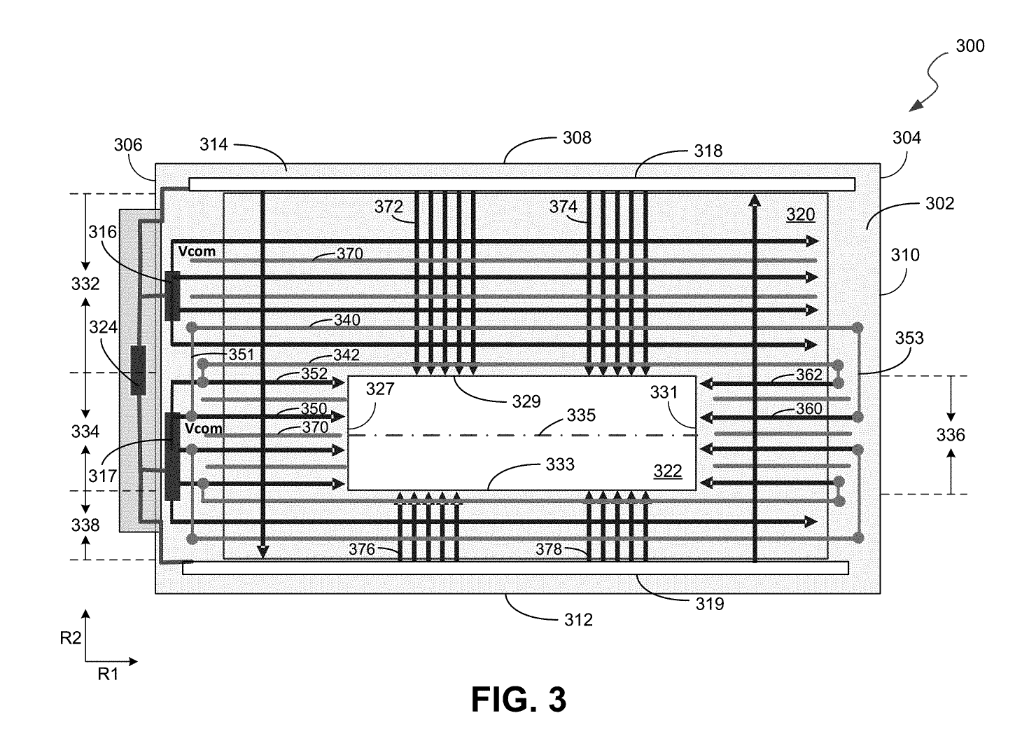

FIG. 3 depicts another embodiment of a display system that incorporates a non-display area. In particular, as shown in FIG. 3, display system 300 includes a substrate 302 defined by an outer periphery 304 that extends along sides 306, 308, 310, and 312. In this embodiment, substrate 302 is rectangular with sides 308 and 312 being longer than sides 306 and 310. An edge region 314 extends inwardly from outer periphery 304. Display system 300 incorporates a display area 320 and a non-display area 322, with the display area 320 of arrayed sub-pixels being positioned inward of edge region 314. Non-display area 322 also is positioned inward of edge region 314 and is surrounded by display area 320. Non-display area 322 is defined by sides 327, 329, 331, and 333, and exhibits a centerline 335 that extends along a first direction R1.

Display system 300 also incorporates data control circuitry, which includes data drivers 316 and 317, as well as gate control circuitry (e.g., GOA circuitry), which includes gate drivers 318 and 319. The data drivers and gate drivers are positioned in edge region 314. Specifically, both data drivers 316 and 317 are positioned in the edge region adjacent side 306, and gate drivers 318 and 319 are positioned in the edge region adjacent sides 308 and 312, respectively. A timing controller (T-con) 324 provides timing signals for coordinating synchronized operations of the data control circuitry and gate control circuitry.

A plurality of data lines (e.g., data line 350) and a plurality of dummy data lines (e.g., dummy data line 340) extend throughout display area 320. In particular, the data lines include: a first set 332 of data lines that extend along first direction R1 from the edge region at side 306 to the edge region at side 310; a second set 334 of data lines that extend along the first direction R1 from the edge region at side 306 to side 327 of the non-display area; a third set 336 of data lines that extend along the first direction R1 from side 331 of the non-display area to the edge region at side 310; and, a fourth set 338 of data lines that extend along the first direction R1 from the edge region at side 306 to the edge region at side 310. Notably, first set 332 of data lines and fourth set 338 of data lines are positioned on opposite sides of non-display area 322. So configured, sets 334 and 336 of the data lines are positioned between sets 332 and 338 of the data lines. The dummy data lines (e.g., dummy data lines 340, 342) extend in the first direction R1, which is generally aligned with the longer sides 308 and 312. The dummy data lines also are interleaved with the plurality of data lines. In some embodiments, the data lines and dummy data lines are provided in an alternating configuration.

At least some of the dummy data lines (e.g., dummy data lines 340, 342) are configured to route data signals around the non-display area from data lines of the second set of the data lines to corresponding data lines of the third set of the data lines. For example, in this embodiment, dummy data line 340 routes data signals provided to data line 350 of the second set 334 of data lines by data control circuitry 317 to data line 360 of the third set 336 of data lines. Dummy data line 342 routes data signals provided to data line 352 of the second set 334 of data lines to data line 362 of the third set 336 of data lines. In this embodiment, data lines 352, 362, as well as dummy data line 342, are positioned between data lines 350, 360 and dummy data line 340. Additionally, data line 350 is positioned closer to centerline 335 of the non-display area than data line 352, with dummy data line 340 being farther from centerline 335 than dummy data line 342. A symmetrical arrangement of data lines and dummy data lines is provided on the other side of the centerline in this embodiment. As described before, the dummy data lines are not directly coupled to the data control circuitry as are the data lines. So configured, data signals are routed from the data control circuitry to the back side of the non-display area by some of the dummy data lines.

In order to route the data signals to the back side (the non-data control side) of non-display area 322, a plurality of start data bus lines (e.g., start data bus line 351) and a plurality of end data bus lines (e.g., end data bus line 353) are provided. In particular, the start data bus lines electrically connect the data lines of set 334 of data lines to corresponding dummy data lines. For example, start data bus line 351 electrically connects data line 350 to dummy data line 340. Additionally, the end data bus lines electrically connect the dummy data lines to corresponding data lines of set 336 of the data lines. For example, end data bus line 353 electrically connects dummy data line 340 to data line 360. In some embodiments, the start data bus lines and the end data bus lines extend along the second direction R2 and are located in the edge region 314.

Also shown in FIG. 3 are several dummy data lines that are not used to route data signals between corresponding data lines. For instance, dummy data line 370 is such a line. In some embodiments, dummy data lines that are not used to route data signals between corresponding data lines may be electrically coupled to a common signal (Vcom) in order to balance parasitic capacitance among sub-pixels in the vicinity of these dummy data lines.

Each of the gate drivers 318 and 319 extends in the first direction R1 and is electrically connected to a plurality of scan lines that extend along a second direction R2. Specifically, gate driver 318 extends along side 308 in edge region 314, and gate driver 319 extends along side 312 in edge region 314. A plurality of scan lines, which include scan lines 372 and 374, are electrically connected to gate driver 318 and extend along the second direction R2 from edge region 314 at side 308 to side 329 of the non-display area 322. Another plurality of scan lines, which include scan lines 376 and 378, are electrically connected to gate driver 319 and extend along the second direction R2 from edge region 314 at side 312 to side 333 of the non-display area 322. Other scan lines that extend along the second direction R2 across the display area 320 are provided. In some embodiments, a subset of these gate lines is controlled by each of the gate drivers 318, 319. By way of example, the gate lines between side 306 and side 327 may be controlled by gate driver 318, whereas the gate lines between side 331 and side 310 may be controlled by gate driver 319. As another example, the gate lines between side 306 and side 327, as well as those between side 331 and side 310, may be interleaved so that alternate ones of the gate lines are controlled by gate drivers 318 and 319. It should be noted that the first direction R1 and the second direction R2 are interlaced and, in some embodiments, are perpendicular to each other.

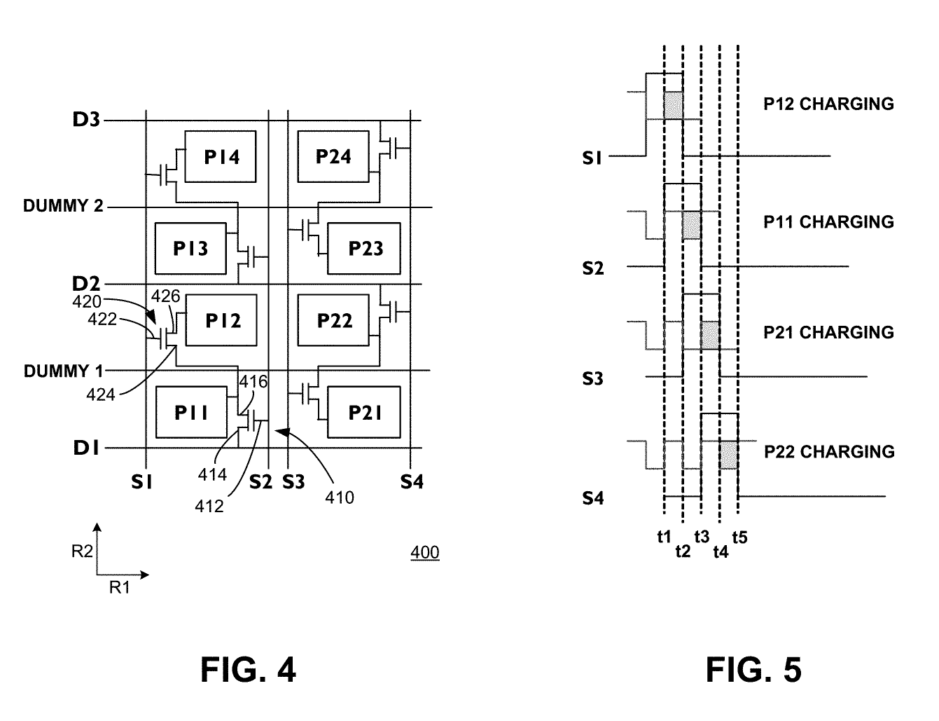

Various sub-pixel configurations may be used in a display system. In this regard, FIG. 4 is a schematic diagram of a portion of an embodiment of pixel array 400 showing several adjacent sub-pixels that may be used. Array 400 includes sub-pixels P11-P14 of a first column and P21-P24 of a second (adjacent) column, with sub-pixels P11 and P21, P12 and P22, P13 and P23, and P14 and P24 being in respective rows. Additionally, sub-pixels P11 and P12, P13 and P14, P21 and P22, and P23 and P24 constitute pairs of sub-pixels that receive data signals based on their respective pairings. In particular, sub-pixels P11 and P12 receive data signals from data line D1, sub-pixels P13 and P14 receive data signals from data line D2, sub-pixels P21 and P22 receive data signals from data line D2, and sub-pixels P23 and P24 receive data signals

MQR 250107-1070

AUVI170803 from data line D3. Note that, in this embodiment, a dummy data line extends between each sub-pixel of a corresponding pair of sub-pixels. By way of example, dummy data line DUMMY 1 extends between P11 and P12, as well as between P21 and P22. The data lines and the dummy data lines extend along a first direction R1.

Array 400 also incorporates scan lines (e.g., scan lines S1-S4) that extend along a second direction R2. With respect to each of the pairs of sub-pixels, a corresponding scan line is electrically connected to one of the sub-pixels and another scan line is electrically connected to the other of the sub-pixels. For instance, scan line S1 is electrically connected to sub-pixel P12 (as well as to P14) and scan line S2 is electrically connected to sub-pixel P11 (as well as to P13), scan line S3 is electrically connected to sub-pixel P21 (as well as to P23) and scan line S4 is electrically connected to sub-pixel P22 (as well as to P24).

Each of the sub-pixels incorporates a transistor for connecting to a corresponding scan line, with one of the transistors of each pair of sub-pixels also being connected to a data line. For example, sub-pixels P11 and P12 incorporate transistors (e.g., TFTs) 410 and 420, respectively. Gate 412 of transistor 410 is electrically connected to scan line S2, and gate 422 of transistor 420 is electrically connected to scan line 51. Additionally, source electrode 414 of transistor 410 is electrically connected to data line D1, with the drain electrode 416 of transistor 410 being electrically connected (such as through a storage capacitor, which is connected to the pixel electrode of P11, described later) to source electrode 424 of transistor 420. Drain electrode 426 of transistor 420 is electrically connected to the pixel electrode of P12.

FIG. 5 is a timing diagram showing charging cycles of several sub-pixels from FIG. 4. In particular, FIG. 5 shows that at time t1, a corresponding scan signal provided by scan line S1 begins a charging cycle for sub-pixel P12 (and for sub-pixel P14). This is followed at time t2 by charging of the other sub-pixel (P11) of the sub-pixel pair owing to a scan signal provided by scan line S2 (sub-pixel P13 also begin charging at t2). Recall that the data for both sub-pixels P11 and P12 of the pair is provided by data line D1. At time t3, a corresponding scan signal provided by scan line S3 begins a charging cycle for sub-pixel P21 (and for sub-pixel P23). This is followed at time t4 by charging of the other sub-pixel (P22) of the sub-pixel pair owing to a scan signal provided by scan line S4 (sub-pixel P24 also begin charging at t4). Recall that the data for both sub-pixels P21 and P22 of the pair is provided by data line D2. So configured, charging of paired sub-pixels positioned in different rows of the array is performed independently, while the paired sub-pixels receive data signals from the same (shared) data line.

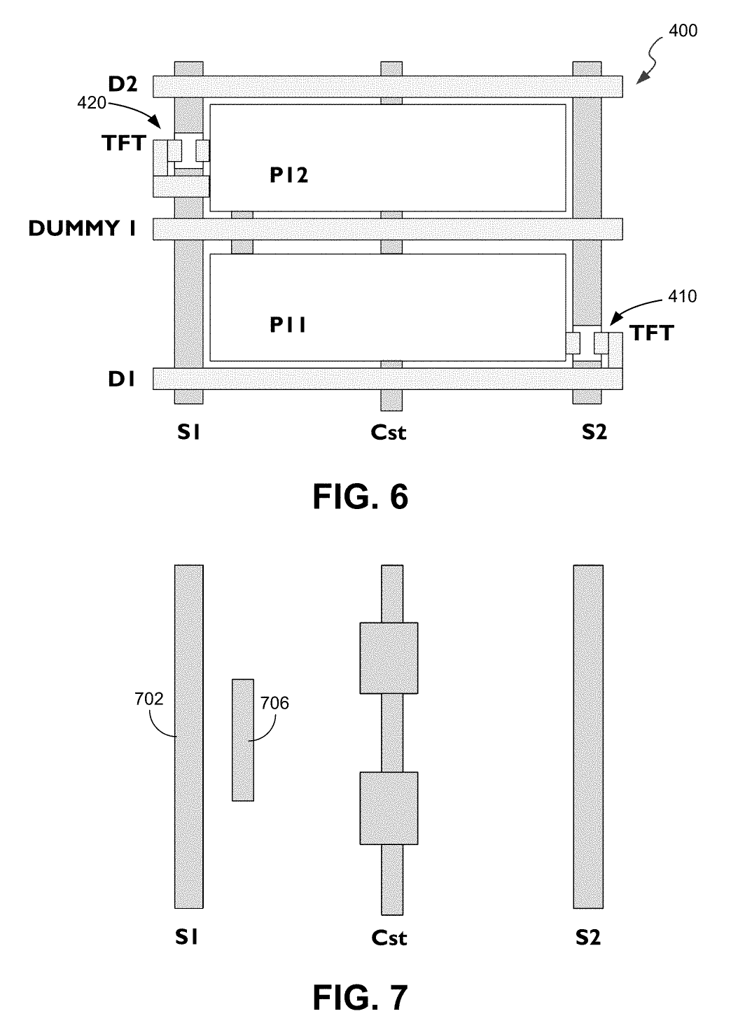

FIG. 6 is a schematic diagram of a portion of an embodiment of array showing a pair of sub-pixels that may be used in a display system. Note that reference characters similar to those used in FIG. 4 are maintained for ease of description. In this regard, FIG. 6 depicts a portion of array 400 that includes sub-pixel pair P11 and P12, as well as data lines D1 and D2, dummy data line DUMMY 1, and scan lines S1 and S2. Also depicted are transistors 410 and 420 and related storage capacitors Cst.

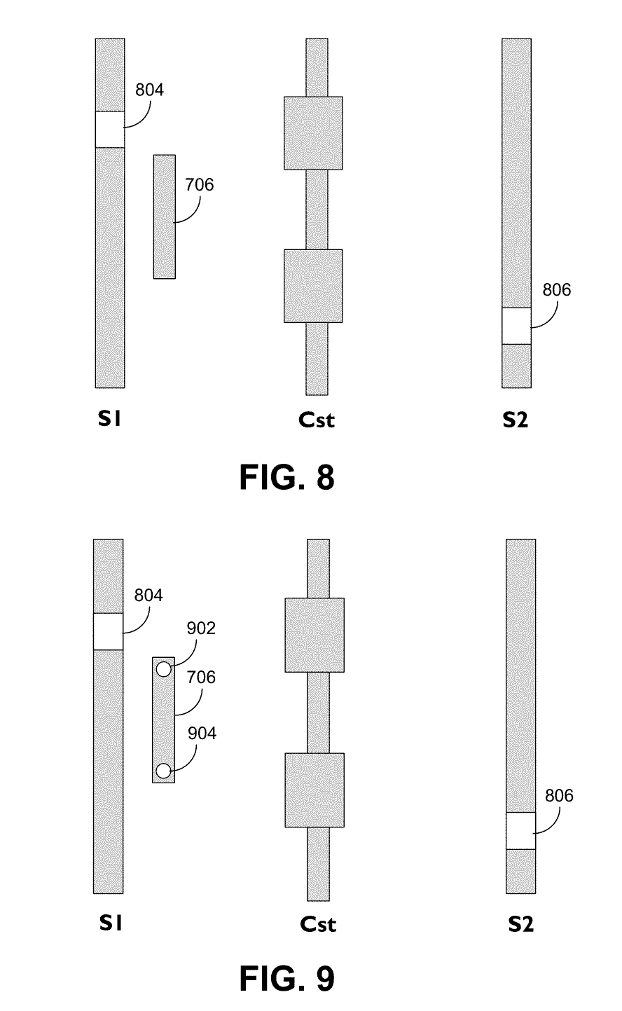

FIGS. 7-12 are schematic diagrams of layouts that may be used in forming an embodiment of a pair of sub-pixels, such as the embodiment of FIG. 6. As shown in FIG. 7, gate metal 702 (e.g., Al, Mo, Cu, Ti) is deposited on a substrate to form scan lines S1 and S2, storage capacitors Cst, and an interconnect 706 that is used for connecting the drain electrode of P11′s transistor (410) to the source electrode of P12′s transistor (420). In FIG. 8, semiconductor material 802 (e.g., poly-Si, a-Si, IGZO) is deposited at locations 804 and 806 to begin formation of the transistors. Then, as depicted in FIG. 9, vias 902 and 904 of gate insulator material (e.g., SiNx, SiOx) are formed in interconnect 706.

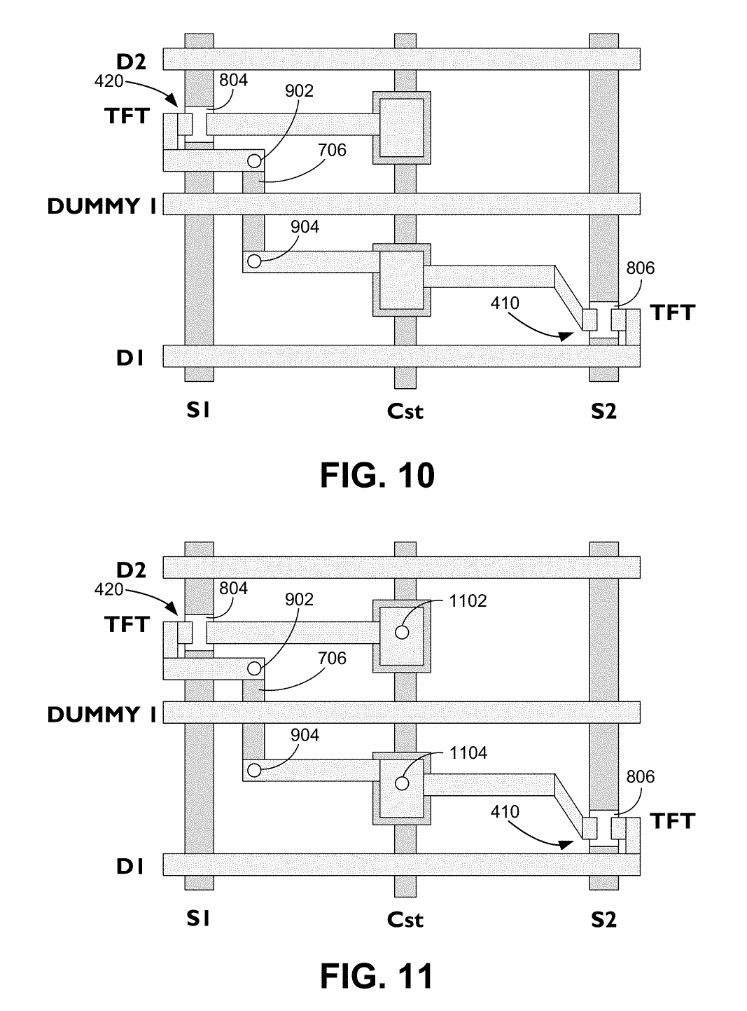

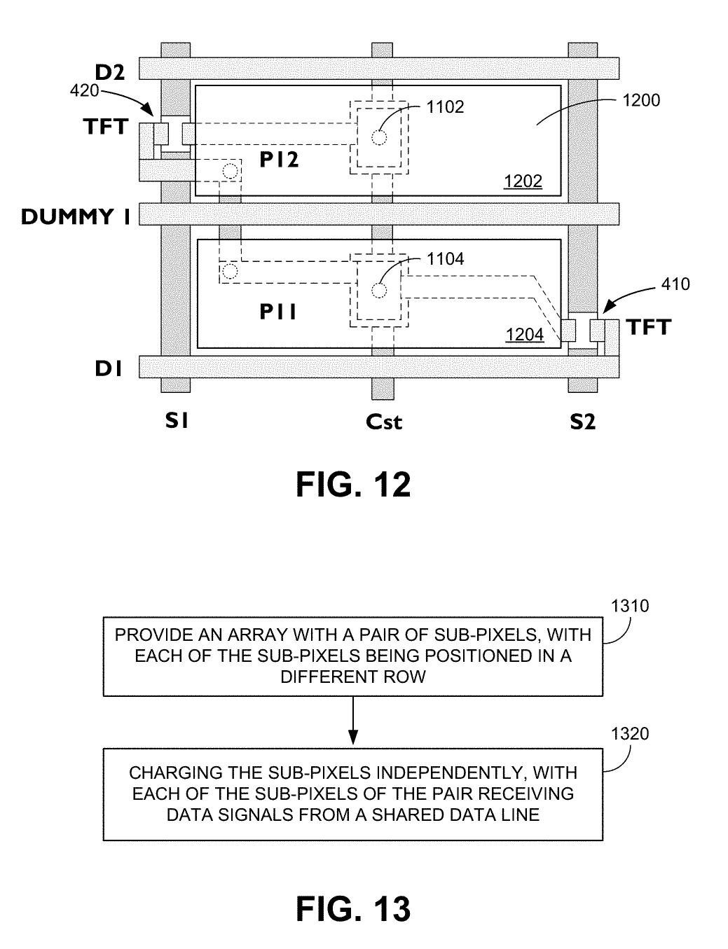

As shown in FIG. 10, source/drain metal 1002 (e.g., Al, Mo, Cu, Ti) is deposited to form data lines D1 and D2, dummy data line DUMMY 1, as well as the various transistor electrodes. In FIG. 11, passivation (e.g., of SiNx, SiOx) with vias 1102 and 1104 are formed at respective storage capacitors. Electrode material 1200 (e.g., transparent electrode material, such as ITO) is deposited to form pixel electrodes 1202 and 1204 as depicted in FIG. 12 to complete the array.

FIG. 13 is a flowchart illustrating an embodiment of a method for controlling an array that uses pairs of sub-pixels. In particular, the method may be construed as beginning at block 1310, in which an array with a pair of sub-pixels is provided, with a first sub-pixel (e.g., P11 of FIG.4) of the pair of sub-pixels being positioned in a first row of the array and a second sub-pixel (e.g., P12 of FIG.4) of the pair of sub-pixels being positioned in another (e.g., adjacent) row of the array. In some embodiments, the first sub-pixel is directly electrically connected to a data line (while the second sub-pixel is not), with a dummy data line extending between the first and second sub-pixels of the pair, and each of the sub-pixels is directly electrically connected to a different scan line. In block 1320, charging of each of the sub-pixels of the pair of sub-pixels is performed independently, with each of the sub-pixels of the pair of sub-pixels receiving data signals from the data line.

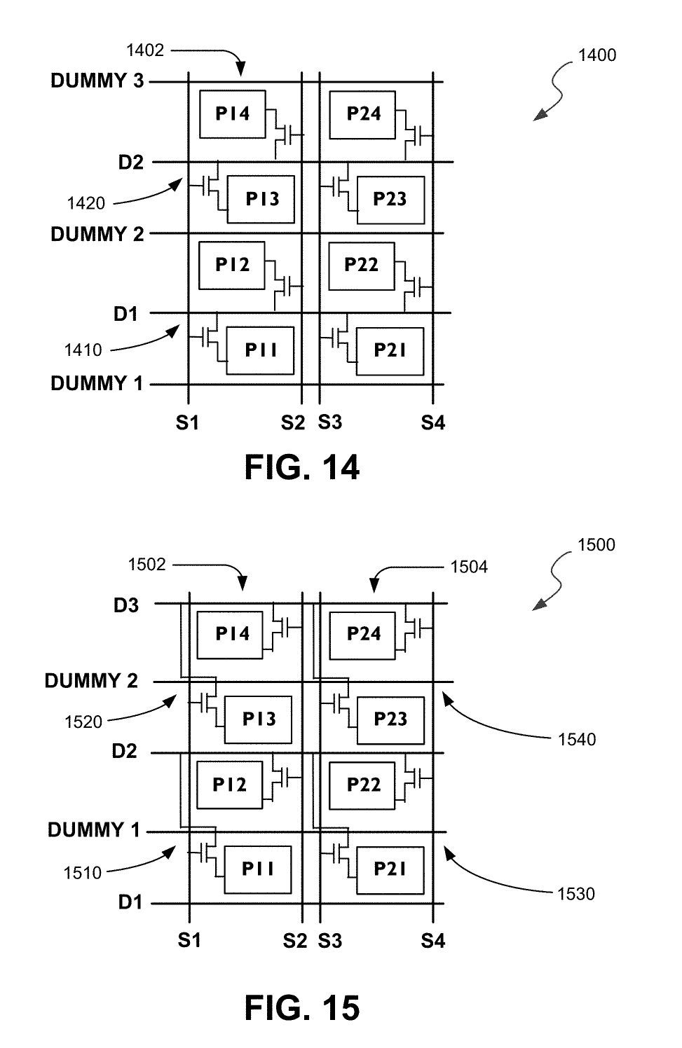

FIG. 14 is a schematic diagram of a portion of another embodiment of an array showing several adjacent sub-pixels. As shown in FIG. 14, array 1400 includes a first pair 1410 of sub-pixels and second pair 1420 of sub-pixels positioned in a first column 1402 of the array. Pair 1410 includes sub-pixels P11 and P12, and pair 1420 includes sub-pixels P13 and P14. In this embodiment, sub-pixel P12 and sub-pixel P13 are positioned adjacent to each other.

Array 1400 also incorporates data lines D1 and D2 and dummy data lines (DUMMY 1, DUMMY 2 and DUMMY 3), with DUMMY 2 being positioned between D1 and D2. Data line D1 extends between and is electrically connected to both sub-pixels of pair 1410. Similarly, data line D2 extends between and is electrically connected to both sub-pixels of pair 1420, with dummy data line (DUMMY 2) extending between pair 1410 and 1420 (specifically, between sub-pixel P12 and sub-pixel P13). In contrast to the arrays described previously, array 1400 does not involve routing of a data signal from one sub-pixel pixel to another of a pair of sub-pixels. In particular, each of the sub-pixels of a pair is connected to a different scan line. In this embodiment, for example, sub-pixels P11 and P13 are connected to scan line 51, and sub-pixels P12 and P14 are connected to scan line S2. It should be noted that such a configuration requires double the scan lines used in an embodiment (e.g., the embodiment of FIG. 4) in which the data signals are routed via one of the sub-pixels of each pair to the other.

FIG. 15 is a schematic diagram of a portion of another embodiment of an array showing several adjacent sub-pixels. As shown in FIG. 15, array 1500 incorporates data lines (e.g., data lines D1, D2, and D3) and alternating dummy data lines (e.g., DUMMY 1 and DUMMY 2). Array 1500 also includes a first pair 1510 of sub-pixels and second pair 1520 of sub-pixels positioned in a first column 1502 of the array, as well as a third pair 1530 of sub-pixels and fourth pair 1540 of sub-pixels positioned in a second column 1504. Pair 1510 includes sub-pixels P11 and P12, pair 1520 includes sub-pixels P13 and P14, pair 1530 includes sub-pixels P21 and P22, and pair 1540 includes sub-pixels P23 and P24.

Using data line D2 as an example, D2 extends between and is electrically connected to two pairs of sub-pixels. Specifically, D2 is connected to the sub-pixels of pairs 1510 and 1530. Each of the sub-pixels from the pairs 1510 and 1530 is connected to a different scan line. In this embodiment, for example, sub-pixel P11 is connected to scan line 51, sub-pixel P12 is connected to scan line S2, sub-pixel P21 is connected to scan line S3, and sub-pixel P22 is connected to scan line S4. Note also that in this embodiment, a data line extends between adjacent pairs of sub-pixels, and a dummy data line extends between the sub-pixels of a pair of sub-pixels. By way of example, data line D2 extends between adjacent pairs 1510 and 1520, and DUMMY 1 extends between P11 and P12.

The embodiments described above are illustrative of the invention and it will be appreciated that various permutations of these embodiments may be implemented consistent with the scope and spirit of the invention.

1. A display system comprising:
a first substrate defined by an outer periphery and having an edge region extending inwardly from the outer periphery;
a display area defined by a plurality of sub-pixels arranged in an array, the display area being positioned inward of the edge region;
a non-display area, which lacks sub-pixels or any associated signal lines, positioned inward of the edge region;
a plurality of data lines comprising:
a first set of the data lines extending along a first direction from the edge region at a first side of the first substrate to the edge region at a second side of the first substrate;
a second set of the data lines extending along the first direction from the edge region at the first side of the first substrate to a first side of the non-display area; and
a third set of the data lines extending along the first direction from a second side of the non-display area to the edge region at the second side of the first substrate; and
a plurality of dummy data lines extending in the first direction and interleaved with the plurality of data lines, with a first set of the plurality of dummy data lines being configured to route data signals from data lines of the second set of the data lines to corresponding data lines of the third set of the data lines;
wherein each of the plurality of dummy data lines extends between sub-pixels of a corresponding pair of the plurality of sub-pixels, and each of the plurality of data lines is configured to provide a corresponding data signal to both sub-pixels of the corresponding pair of sub-pixels.

2. The display system of claim 1, further comprising:
gate control on array (GOA) circuitry in the edge region and extending in the first direction; and
a plurality of scan lines electrically connected to the GOA circuitry and extending along a second direction.

3. The display system of claim 1, wherein:
the plurality of dummy data lines comprises a first set of dummy data lines interleaved with the first set of the data lines, a second set of dummy data lines interleaved with the second set of the data lines, and a third set of dummy data lines interleaved with the third set of the data lines;
the display system further comprises:
a plurality of start data bus lines comprising a first set of start data bus lines connecting the data lines of the first set of the data lines to corresponding dummy data lines of the first set of dummy data lines, and a second set of start data bus lines connecting the data lines of the second set of the data lines to corresponding dummy data lines of the second set of dummy data lines; and
a plurality of end data bus lines connecting the dummy data lines of the second set of dummy data lines to corresponding data lines of the third set of the data lines.

4. The display system of claim 3, wherein:
the second set of the data lines comprises a first data line and a second data line;
the second set of dummy data lines comprises a first dummy data line and a second dummy data line; and
the second data line and the second dummy data line are positioned between the first data line and the first dummy data line.

5. The display system of claim 4, wherein:
the non-display area exhibits a centerline extending along the first direction; and
the first data line is positioned closer to the centerline than is the second data line.

6. The display system of claim 3, wherein the plurality of start data bus lines and the plurality of end data bus lines extend along the second direction.

7. The display system of claim 1, wherein the non-display area is surrounded by the display area.

8. The display system of claim 7, wherein:
the display system further comprises a fourth set of the data lines extending along the first direction from the edge region at the first side of the first substrate to the edge region at the second side of the first substrate; and
the second set of the data lines and the third set of the data lines are positioned between the first set of the data lines and the fourth set of the data lines.

9. The display system of claim 7, further comprising:
first GOA circuitry in the edge region and extending in the first direction;
second GOA circuitry in the edge region and extending in the first direction;
a first plurality of scan lines electrically connected to the first GOA circuitry and extending along a second direction from the edge region to a third side of the non-display area; and
a second plurality of scan lines electrically connected to the second GOA circuitry and extending along the second direction from the edge region to a fourth side of the non-display area.

10. The display system of claim 1, further comprising data control circuitry positioned only in the edge region at the first side of the first substrate, the data control circuitry being configured to provide the data signals directly to the first set of the data lines and the second set of the data lines.

11. The display system of claim 10, wherein the data control circuitry is further configured to provide the data signals to the third set of the data lines via the second set of the data lines and the first set of the plurality of dummy data lines.

12.-13. (canceled)

14. The display system of claim 1, wherein:
one of the dummy data lines extends between a first pair of sub-pixels, the first pair of sub-pixels including a first sub-pixel and a second sub-pixel;
the display system further comprises a first scan line and a second scan line, each of which extends along a second direction; and
the first scan line is electrically connected to the first sub-pixel and the second scan line is electrically connected to the second sub-pixel.

15. The display system of claim 14, wherein:
the display system further comprises a second pair of sub-pixels adjacent in the array to the first pair of sub-pixels, the second pair of sub-pixels including a third sub-pixel and a fourth sub-pixel;
another one of the dummy data lines extends between the second pair of sub-pixels; and
the second scan line is electrically connected to the fourth sub-pixel.

16. The display system of claim 1, wherein:
the first substrate comprises a third side extending from the first side to the second side, and a fourth side extending from the first side to the second side;
each of the third side and the fourth side is longer than the first side and the second side; and
the third side and the fourth side are aligned with the first direction.

17. The display system of claim 1, wherein:
the display system further comprises a first pair of sub-pixels and a second pair of sub-pixels positioned in a first column of the array, the first pair of sub-pixels including a first sub-pixel and a second sub-pixel, the second pair of sub-pixels including a third sub-pixel and a fourth sub-pixel, the second sub-pixel being positioned adjacent to the third sub-pixel;
a first data line of the plurality of data lines is electrically connected to each of the first sub-pixel and the second sub-pixel and extends therebetween;
a second data line of the plurality of data lines is electrically connected to each of the third sub-pixel and the fourth sub-pixel and extends therebetween; and
one of the dummy data lines extends between the first pair of sub-pixels and the second pair of sub-pixels.

18. The display system of claim 17, wherein:
the display system further comprises a first scan line and a second scan line, each of which extends along a second direction; and
the first scan line is electrically connected to the first sub-pixel and the third sub-pixel, and the second scan line is electrically connected to the second sub-pixel and the fourth sub-pixel.

19. The display system of claim 1, wherein at least another of the plurality of dummy data lines is electrically coupled to a common signal (Vcom).
